(19) United States
(12) Patent Application Publication
(10) Pub. No.: US 2025/0157844 A1
(43) Pub. Date: May 15, 2025

(54) CERAMIC SUBSTRATE, ELECTROSTATIC CHUCK AND SUBSTRATE FIXING DEVICE

(71) Applicant: SHINKO ELECTRIC INDUSTRIES CO., LTD., Nagano-shi (JP)

(72) Inventor: Ryosuke Hori, Nagano (JP)

(21) Appl. No.: 18/943,163

(22) Filed: Nov. 11, 2024

(30) Foreign Application Priority Data
Nov. 13, 2023 (JP) 2023-192877

(51) Int. Cl. H01L 21/683; H01J 37/32

(52) U.S. Cl. CPC H01L 21/6833; H01J 37/32715; H01J 2237/2007

(57) ABSTRACT

A ceramic substrate includes a first phase made of alumina, and a second phase made of yttrium aluminum garnet containing silicon.

### CROSS-REFERENCE TO RELATED APPLICATIONS

This application claims priority from Japanese Patent Application No. 2023-192877 filed on Nov. 13, 2023, the contents of which are incorporated herein by reference

### TECHNICAL FIELD

The present disclosure relates to a ceramic substrate, an electrostatic chuck, and a substrate fixing device.

### BACKGROUND ART

An electrostatic chuck including alumina and yttrium aluminum garnet (Y₃Al₅O₁₂: YAG) is known. According to this electrostatic chuck, high resistance to plasma can be achieved by including YAG. However, in order to manufacture an electrostatic chuck including alumina and YAG with a high theoretical density ratio without using a sintering additive, high temperature and long-term firing is required. Additionally, an electrostatic chuck consisting of alumina and YAG with addition of cerium is suggested.

### CITATION LIST

### Patent Literature

PTL 1: JP2018-186209A
PTL 2: JP2013-502721A

### SUMMARY OF INVENTION

However, when a green sheet used as a material of the electrostatic chuck includes cerium, the cerium may diffuse out of the green sheet during firing and attach to an inside of a firing furnace. Therefore, it is desirable to achieve a high theoretical density ratio without using cerium.

The present disclosure is to provide a ceramic substrate, an electrostatic chuck, and
a substrate fixing device, which can achieve a high theoretical density ratio.

According to one aspect of the present disclosure, a ceramic substrate includes:
a first phase made of alumina; and
a second phase made of yttrium aluminum garnet containing silicon.

According to the present disclosure, it is possible to achieve a high theoretical density ratio.

### BRIEF DESCRIPTION OF DRAWINGS

FIG. 1 is a plan view illustrating a substrate fixing device according to an embodiment.

FIG. 2 is a cross-sectional view illustrating the substrate fixing device according to the embodiment.

FIG. 3 is a cross-sectional view illustrating a configuration of a ceramic substrate.

FIGS. 4A and 4B are cross-sectional views illustrating a method for manufacturing an electrostatic chuck.

FIGS. 5A to 5C are diagrams illustrating cross-sectional SEM images of ceramic substrates.

FIGS. 6A to 6D are diagrams illustrating a result of SEM-EDX (1 thereof).

FIGS. 7A to 7D are diagrams illustrating a result of SEM-EDX (2 thereof).

FIG. 8 is a diagram illustrating a relationship between temperature and volume resistivity.

FIG. 9 is a diagram illustrating the analysis results of FIG. 6D by indicating boundaries between the regions where silicon was detected and the regions where silicon was not detected with broken lines.

FIG. 10 is a diagram illustrating the analysis results of FIG. 7D by indicating boundaries between the regions where silicon was detected and the regions where silicon was not detected with broken lines.

### DESCRIPTION OF EMBODIMENTS

Embodiments of the present disclosure will be described in detail below with reference to the accompanying drawings. Note that, in the specification and drawings, the constitutional elements having substantially the same functional configurations are denoted with the same reference signs, and the redundant descriptions may be omitted.

### [Configuration of Substrate Fixing Device]

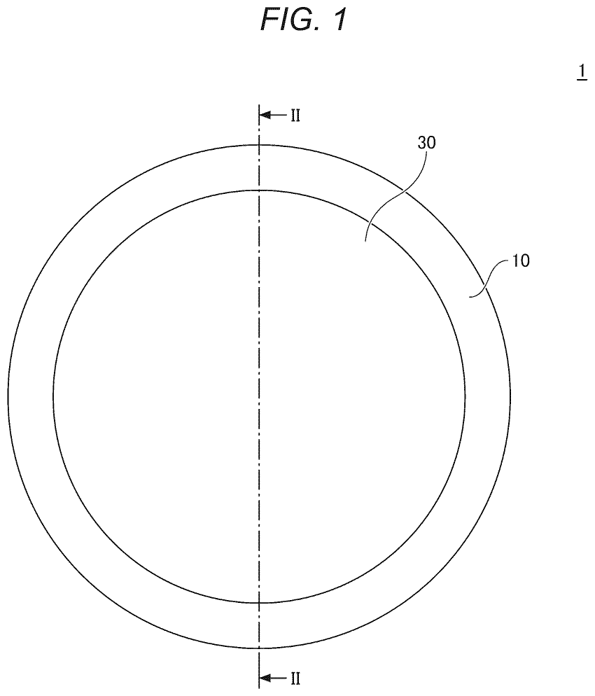

First, a configuration of a substrate fixing device according to an embodiment will be described. FIG. 1 is a plan view illustrating a substrate fixing device according to an embodiment. FIG. 2 is a cross-sectional view illustrating the substrate fixing device according to the embodiment. FIG. 2 corresponds to a cross-sectional view taken along line II-II in FIG. 1.

As shown in FIGS. 1 and 2, a substrate fixing device 1 according to the embodiment includes, main constitutional elements, a base plate 10, an adhesive layer 20, and an electrostatic chuck 30. The substrate fixing device 1 is a device that adsorbs and holds an object such as a substrate (a wafer or the like), which is a target object to be adsorbed, by the electrostatic chuck 30 fixed on one surface 10a of the base plate 10.

Note that, in the present disclosure, it is assumed that the description ‘in a plan view’ indicates that a target object is seen from a normal direction of the surface 10a of the base plate 10, and the description ‘planar shape’ indicates a shape of the target object as seen from the normal direction of the surface 10a of the base plate 10.

The base plate 10 is a member for mounting the electrostatic chuck 30. A thickness of the base plate 10 is, for example, about 20 mm to 40 mm. The base plate 10 is formed of, for example, aluminum, and can be used as an electrode or the like for controlling plasma. By supplying predetermined high-frequency electric power to the base plate 10, the energy for causing ions and the like in a generated plasma state to collide with the substrate adsorbed on the electrostatic chuck 30 can be controlled to effectively perform etching processing.

The electrostatic chuck 30 is a part that adsorbs and holds a wafer, which is a target object to be adsorbed. A planar shape of the electrostatic chuck 30 is circular, for example. A diameter of the wafer, which is a target object to be adsorbed of the electrostatic chuck 30, is, for example, 8 inches, 12 inches, or 18 inches.

The electrostatic chuck 30 is provided on one surface 10a of the base plate 10 via the adhesive layer 20. A material of the adhesive layer 20 is, for example, a silicone-based adhesive. A thickness of the adhesive layer 20 is, for example, about 0.1 mm to 1.5 mm. The adhesive layer 20 bonds the base plate 10 and the electrostatic chuck 30, and has an effect of reducing stress generated due to a difference in thermal expansion coefficient between the electrostatic chuck 30 made of ceramic and the base plate 10 made of aluminum.

The electrostatic chuck 30 includes a ceramic substrate 31, positive electrodes 32P and negative electrodes 32N. An upper surface of the ceramic substrate 31 is a placement surface 31a on which a target object to be adsorbed is placed. The electrostatic chuck 30 is, for example, a Coulomb force type electrostatic chuck. The electrostatic chuck 30 may also be a Johnson Rahbek type electrostatic chuck or a gradient type electrostatic chuck.

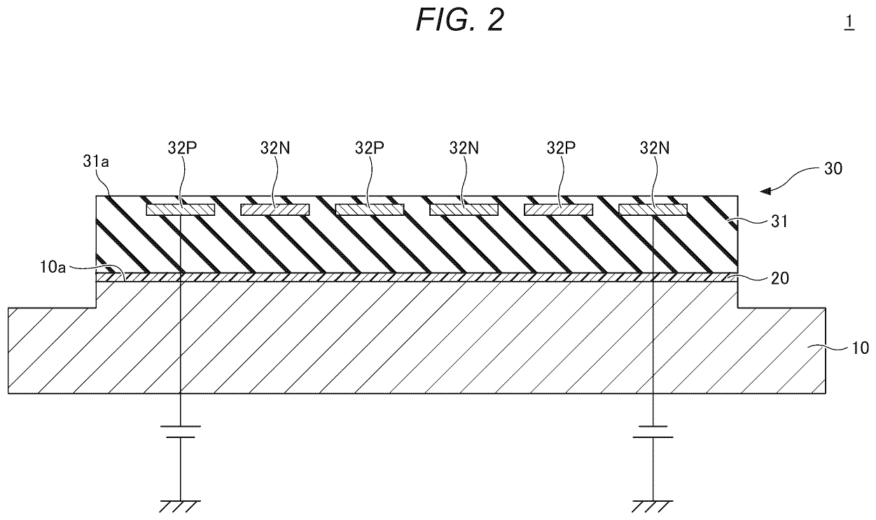

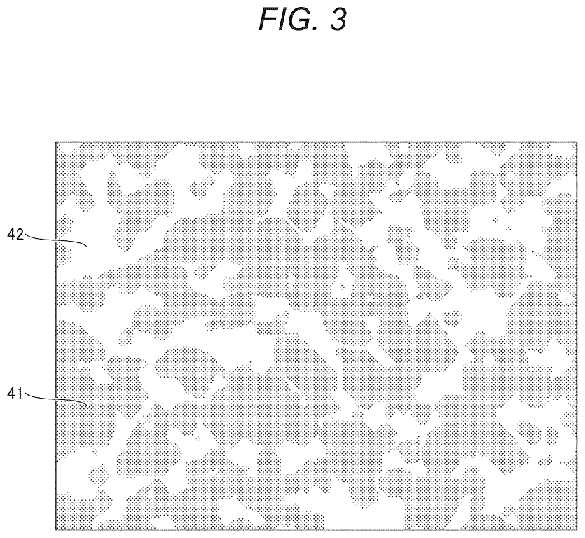

A thickness of the ceramic substrate 31 is, for example, about 1 mm to 6 mm, and a relative permittivity (kHz) of the ceramic substrate 31 is, for example, about 9 to 10. FIG. 3 is a cross-sectional view illustrating a configuration of the ceramic substrate.

As shown in FIG. 3, the ceramic substrate 31 includes a first phase 41 made of alumina (Al₂O₃) and a second phase 42 made of yttrium aluminum garnet (YAG) including silicon (Si). The first phase 41 includes crystals of Al₂O₃, and the second phase 42 includes crystals of YAG including Si. The first phase 41 and the second phase 42 are mixed in the ceramic substrate 31. For example, a proportion of the first phase 41 is greater than that of the second phase 42. In any cross-section of the ceramic substrate 31, for example, a total area of the first phase 41 is 1.2 times or greater and 1.8 times or less a total area of the second phase 42. The total area of the first phase 41 may be 1.3 times or greater and 1.7 times or less, or 1.4 times or greater and 1.6 times or less the total area of the second phase 42.

Although the ceramic substrate 31 may include empty holes (pores), a theoretical density ratio (ratio of actual density to theoretical density) of the ceramic substrate 31 is preferably 98.0% or greater, more preferably 98.5% or greater, and even more preferably 99.0% or greater.

A proportion of silicon in the ceramic substrate 31 is, for example, 0.10 mass % or more and 0.50 mass % or less. The proportion of silicon in the ceramic substrate 31 is preferably 0.12 mass % or more and 0.45 mass % or less, and more preferably 0.14 mass % or more and 0.40 mass % or less.

In addition, a volume resistivity of the ceramic substrate 31 at 300° C. is preferably 1.0×10¹⁵ Ω·cm or greater, more preferably 1.1×10¹⁶ Ω·cm or greater, and even more preferably 1.2×10¹⁷ Ω·cm or greater.

The positive electrodes 32P and the negative electrodes 32N are bipolar electrostatic electrodes formed of thin films, and are embedded in the ceramic substrate 31. The positive electrodes 32P and the negative electrodes 32N are formed in, for example, a comb-like electrode pattern, and teeth of each electrode are alternately arranged side by side at predetermined intervals. The positive electrodes 32P and the negative electrodes 32N are connected to a power supply provided outside of the substrate fixing device 1, and generate adsorption force by static electricity between the electrodes and the wafer when a predetermined voltage is applied from the power supply. Thereby, it is possible to adsorb and hold the wafer on the placement surface 31a of the ceramic substrate 31 of the electrostatic chuck 30. When a higher voltage is applied between the positive electrode 32P and the negative electrode 32N, the adsorption force becomes stronger. As materials of the positive electrode 32P and the negative electrode 32N, tungsten, molybdenum, or the like is used, for example.

As shown in FIG. 2, the base plate 10, the adhesive layer 20, and the ceramic substrate 31 are provided with a voltage supply path for applying a positive (+) voltage to the positive electrode 32P and a negative (−) voltage to the negative electrode 32N.

In the ceramic substrate 31, a heating element (heater) that generates heat when a voltage is applied from the outside of the substrate fixing device 1 and heats the placement surface 31a of the ceramic substrate 31 to a predetermined temperature may also be provided.

### [Method for Manufacturing Electrostatic Chuck]

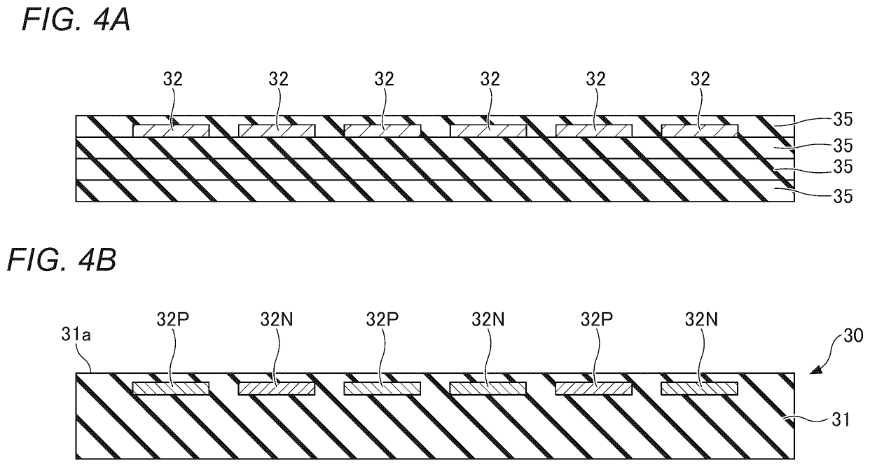

Next, a method for manufacturing the electrostatic chuck 30 will be described. FIGS. 4A and 4B are cross-sectional views illustrating a method for manufacturing the electrostatic chuck 30.

First, as shown in FIG. 4A, a plurality of green sheets 35, each with a thickness of about 0.5 mm to 0.6 mm and including powders of alumina (Al₂O₃), yttria (Y₂O₃), and silicon dioxide (SiO₂), are stacked. In the green sheet 35, a molar concentration of alumina is, for example, 80 mol % or more and 90 mol % or less, a molar concentration of yttria is, for example, 10 mol % or more and 20 mol % or less, and a molar concentration of silicon dioxide is, for example, 0.10 mol % or more and 0.70 mol % or less. The molar concentration of silicon dioxide is preferably 0.20 mol % or more and 0.60 mol % or less, and more preferably 0.30 mol % or more and 0.50 mol % or less. In addition, a metal paste 32, such as tungsten, for forming positive electrodes 32P and negative electrodes 32N is provided in the middle layer of the plurality of green sheets 35 by printing or the like.

Note that the number of the green sheets 35 stacked is not limited, and, for example, several to several dozen green sheets 35 can be stacked.

Next, the plurality of green sheets 35 and the metal paste 32 are heated to a temperature of about 1500° C. Then, by maintaining this state for several hours, each green sheet 35 and the metal paste 32 are sintered. As a result, as shown in FIG. 4B, a ceramic substrate 31 is obtained from the plurality of green sheets 35, and positive electrodes 32P and negative electrodes 32N are obtained from the metal paste 32. At this time, a portion of alumina and yttria react to produce YAG, and silicon in silicon dioxide is introduced into YAG, producing a first phase 41 and a second phase 42.

In this way, the electrostatic chuck 30 can be manufactured.

When manufacturing a substrate fixing device 1, a separate base plate 10 is prepared, the base plate 10 and the electrostatic chuck 30 are bonded together using an uncured adhesive, and the adhesive is cured to form an adhesive layer 20. In this way, the substrate fixing device 1 according to the embodiment can be manufactured.

In the substrate fixing device 1, the ceramic substrate 31 has the first phase 41 made of alumina and the second phase 42 made of YAG containing silicon. By including YAG in the second phase 42, high plasma resistance can be obtained. Additionally, in the manufacturing process of the ceramic substrate 31, silicon dioxide is used as a sintering additive. For this reason, a high theoretical density ratio can be achieved without requiring particularly high temperatures or long times during firing. Furthermore, silicon is difficult to be released to the outside during the firing of the green sheets 35 and tends to remain in the green sheets 35. For this reason, contamination of a firing furnace or the like used in firing can be avoided.

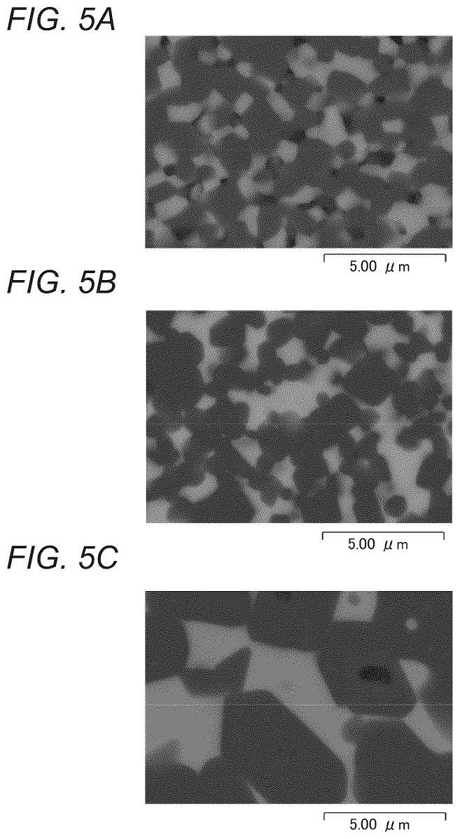

Here, scanning electron microscope (SEM) images of cross-sections of three types of ceramic substrate samples prepared by the inventors of the present application (sample No. 1, sample No. 2, and sample No. 3) are described. FIGS. 5A to 5C are diagrams illustrating cross-sectional SEM images of ceramic substrates. FIG. 5A shows a cross-sectional SEM image of sample No. 1 to which silicon dioxide was not added during the manufacturing process. FIG. 5B shows a cross-sectional SEM image of sample No. 2 to which silicon dioxide of 0.32 mol % was added during the manufacturing process. FIG. 5C shows a cross-sectional SEM image of sample No. 3 to which silicon dioxide of 0.65 mol % was added during the manufacturing process.

The cross-sectional SEM image of sample No. 1 of FIG. 5A shows many pores (especially dark black portions), and the theoretical density ratio of the ceramic substrate was 97.0%. The cross-sectional SEM image of sample No. 3 of FIG. 5C shows few pores, and the theoretical density ratio of the ceramic substrate was 98.5%. The cross-sectional SEM image of sample No. 2 of FIG. 5B shows particularly few pores, and the theoretical density ratio of the ceramic substrate was 99.2%. Note that the theoretical density ratio is a value measured based on Archimedes' principle.

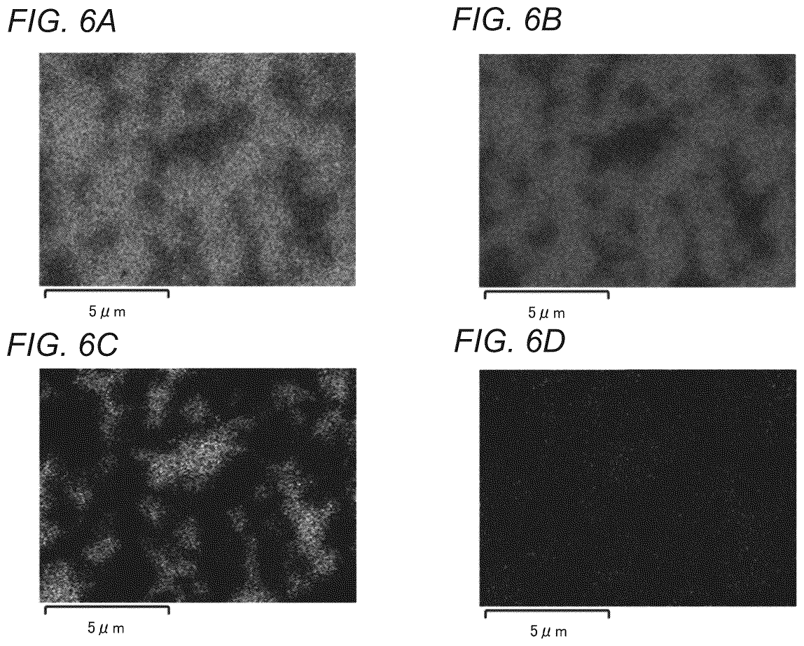

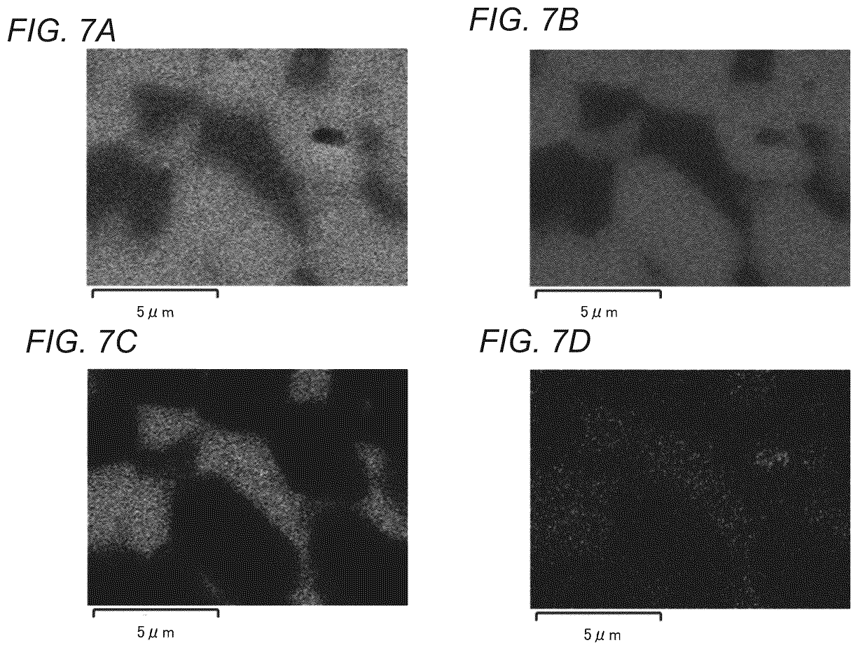

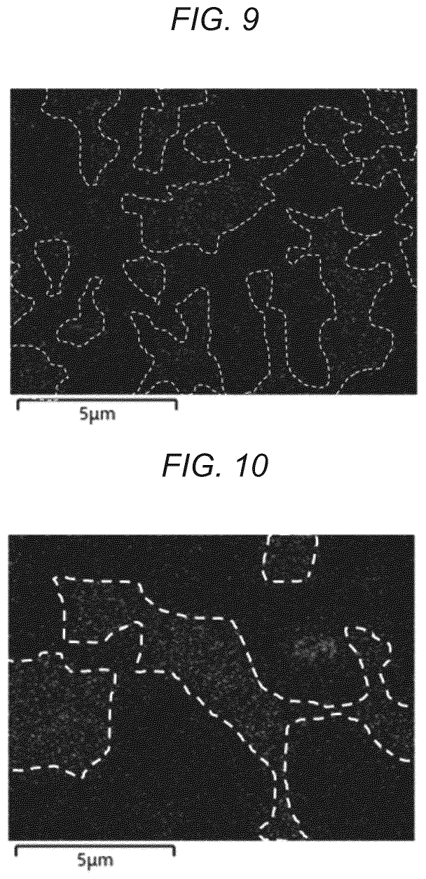

SEM-energy dispersive X-ray spectroscopy (EDX) was also performed for sample No. 2 and sample No. 3. Results thereof are shown in FIGS. 6A to 7D. FIGS. 6A to 6D are diagrams illustrating a result of SEM-EDX performed for sample No. 2, and FIGS. 7A to 7D are diagrams illustrating a result of SEM-EDX performed for sample No. 3. In addition, FIG. 6A and FIG. 7A show the analysis results of oxygen, FIG. 6B and FIG. 7B show the analysis results of aluminum, FIG. 6C and FIG. 7C show the analysis results of yttrium, and FIG. 6D and FIG. 7D show the analysis results of silicon. FIG. 9 shows the analysis results of FIG. 6D by indicating boundaries between the regions where silicon was detected and the regions where silicon was not detected with broken lines in order to understand easily. FIG. 10 shows the analysis results of FIG. 7D by indicating boundaries between the regions where silicon was detected and the regions where silicon was not detected with broken lines in order to understand easily.

As shown in FIGS. 6A to 6D and 7A to 7D, silicon was mainly detected in the regions where yttrium was detected. This indicates that silicon is included in YAG.

In addition, the inventors of the present invention performed X-ray diffraction (XRD) analysis. As a result, no amorphous phase originating from silicon dioxide was detected in any of sample No. 1, sample No. 2, and sample No. 3.

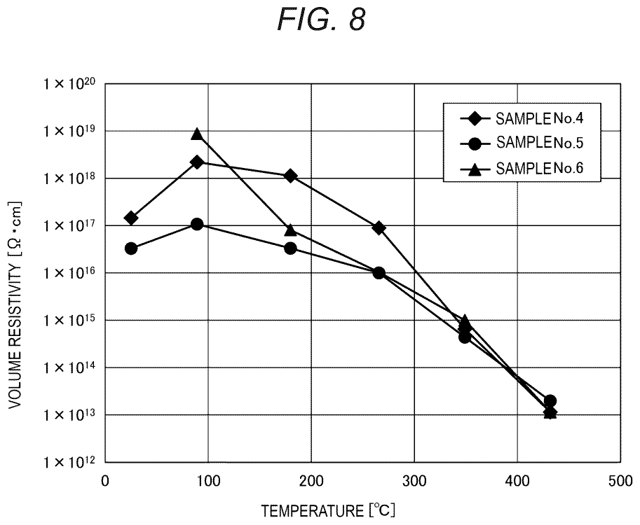

Next, a test on the volume resistivity of the ceramic substrate conducted by the inventor of the present invention will be described. In the test, three types of samples (sample No. 4, sample No. 5, and sample No. 6) were prepared. Sample No. 4 is based on the above embodiment and includes the first phase 41 and the second phase 42. The proportion of silicon in the ceramic substrate is 0.17 mass %. Sample No. 5 includes alumina with a purity of 99.9 mass %. Sample No. 6 consists of alumina and YAG with addition of cerium. In the manufacturing process, 0.5 mol % of cerium dioxide (CeO₂) was added to the green sheet as a cerium source. Then, the change in volume resistivity with temperature was measured. A result thereof is shown in FIG. 8. FIG. 8 is a diagram illustrating a relationship between temperature and volume resistivity.

As shown in FIG. 8, the volume resistivity of 1×10¹⁵ Ω·cm or higher at 300° C. was obtained in any of sample No. 4, sample No. 5, and sample No. 6. That is, in sample No. 4, the volume resistivity comparable to those of sample No. 5 and sample No. 6 was obtained.

Although the preferred embodiments have been described in detail, the present disclosure is not limited to the above-described embodiments, and a variety of changes and replacements can be made for the above-described embodiments without departing from the scope defined in the claims.

What is claimed is:

1. A ceramic substrate comprising:
a first phase made of alumina; and
a second phase made of yttrium aluminum garnet containing silicon.

2. The ceramic substrate according to claim 1, wherein a proportion of silicon is 0.10 mass % or more and 0.50 mass % or less.

3. The ceramic substrate according to claim 1, wherein a proportion of the first phase is greater than a proportion of the second phase.

4. The ceramic substrate according to claim 1, wherein, in a cross-section, a total area of the first phase is 1.2 times or greater and 1.8 times or less a total area of the second phase.

5. An electrostatic chuck comprising:
the ceramic substrate according to claim 1; and
an electrode embedded in the ceramic substrate.

6. The electrostatic chuck according to claim 5, wherein a proportion of the first phase is greater than a proportion of the second phase.

7. The electrostatic chuck according to claim 5, wherein, in a cross-section, a total area of the first phase is 1.2 times or greater and 1.8 times or less a total area of the second phase.

8. A substrate fixing device comprising:
a base plate; and
the electrostatic chuck according to claim 5 fixed on the base plate.

9. The substrate fixing device according to claim 8, wherein a proportion of the first phase is greater than a proportion of the second phase.

10. The substrate fixing device according to claim 8, wherein, in a cross-section, a total area of the first phase is 1.2 times or greater and 1.8 times or less a total area of the second phase.
